(19) United States
(12) Patent Application Publication
(10) Pub. No.: US 2010/0140678 A1
(43) Pub. Date: Jun. 10, 2010

(54) FLASH MEMORY DEVICE AND MANUFACRUTING METHOD THE SAME

(76) Inventor: Cheon-Man Shim, Yeongdeungpo-gu (KR)

Correspondence Address: SHERR & VAUGHN, PLLC, 620 HERNDON PARKWAY, SUITE 320, HERNDON, VA, 20170, US

(21) Appl. No.: 12/620,823

(22) Filed: Nov. 18, 2009

(30) Foreign Application Priority Data
Dec. 8, 2008 (KR) 10-2008-0124242

(51) Int. Cl. H01L 29/788; H01L 29/792; H01L 21/336

(52) U.S. Cl. 257/314; 438/257; 438/287; 257/E29.3; 257/E29.309; 257/E21.422; 257/E21.423

(57) ABSTRACT

A flash memory device and a method of manufacturing a flash memory device. A flash memory device may include a device isolation layer and/or an active area formed on and/or over a semiconductor substrate. A flash memory device may include a memory gate formed on and/or over an active area and/or a control gate formed on and/or over a semiconductor substrate including a memory gate. Active areas may be formed having substantially the same interval with bit lines. A common source line area where a common source line contact may be formed may include a bridge formed between active areas. Neighboring active areas may be connected.

The present application claims priority under 35 U.S.C. 119 to Korean Patent Application No. 10-2008-0124242 (filed on Dec. 8, 2008) which is hereby incorporated by reference in its entirety.

### BACKGROUND

Embodiments relate to an electric device and methods of manufacturing an electric device. Some embodiments relate to a flash memory device and a method of manufacturing a flash memory device.

A flash memory device may include a nonvolatile memory medium in which stored data may not be damaged even if a power supply may be turned off. A flash memory device may include a relatively high speed of data processing including recording, reading and/or deleting, for example. Accordingly, a flash memory device may be widely used, for example, for a Bios of a personal computer (PC), for storing data of a set-top box, a printer and/or a network server. A flash memory device may be broadly used in a digital camera, a cellular phone, and the like.

A flash memory device may be categorized as a stack gate type semiconductor device, which may include a floating gate, and/or as a semiconductor device, which may include a silicon-oxide-nitride-oxide silicon (SONOS) structure. A flash memory device may include a structure in which unit cells may be concentrated in a relatively narrow area to be competitive. Accordingly, a common source line may be formed rather than forming a contact on and/or over sources. However, although a common source line may be formed to be larger than a bit line, it may affect adjacent bit lines due to an irregular size and/or a uniform pattern may not be formed.

### SUMMARY

Embodiment relate to a flash memory device and a method of manufacturing a flash memory device. According to embodiments, a flash memory device may include a device isolation layer and/or an active area formed on and/or over a semiconductor substrate. In embodiments, a flash memory device may include a memory gate formed on and/or over an active area. In embodiments, a flash memory device may include a control gate formed on and/or over a semiconductor substrate including a memory gate. In embodiments, active areas may be formed including substantially the same interval with bit lines. In embodiments, a common source line area where a common source line contact may be formed may include a bridge formed between active areas. In embodiments, neighboring active areas may be connected.

According to embodiments, a method of manufacturing a flash memory device may include defining an active area by forming a device isolation layer on and/or over a semiconductor substrate. In embodiments, a method of manufacturing a flash memory device may include forming a memory gate on and/or over a semiconductor substrate including an active area. In embodiments, a method of manufacturing a flash memory device may include forming a control gate on and/or over a semiconductor substrate including a memory gate. In embodiments, active areas may be formed including substantially the same interval with bit lines. In embodiments, a common source line area where a common source line contact may be formed may include a bridge formed between active areas. In embodiments, neighboring active areas may be connected.

### DRAWINGS

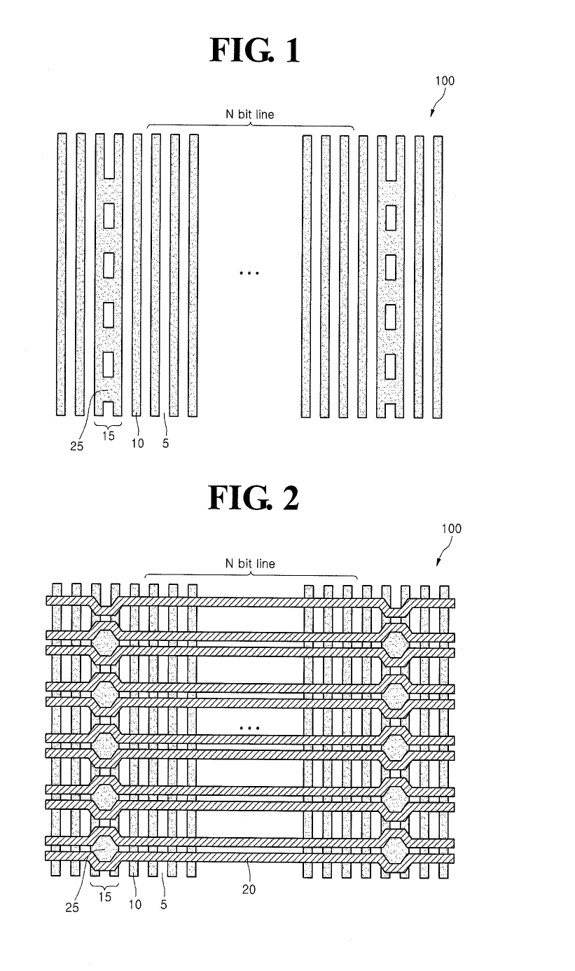

Example FIG. 1 to FIG. 3 are plan views illustrating a flash memory device in accordance with embodiments.

### DESCRIPTION

Embodiments relate to a method of manufacturing a flash memory device. Referring to example FIG. 1 to FIG. 3, plan views illustrate a flash memory device in accordance with embodiments. Referring to FIG. 1, active area 10 may be defined by forming device isolation layer 5 on and/or over semiconductor substrate 100. According to embodiments, a trench may be formed on and/or over semiconductor substrate 100. In embodiments, dielectric material may be buried on and/or over a trench, which may enable a formation of device isolation layer 5. In embodiments, active areas 10 may be formed having substantially the same interval as bit lines.

According to embodiments, bridge 25 may connect active areas 10. In embodiments, bridge 25 may be formed in an area where a common source line contact may be formed. In embodiments, bridge 25 may be formed on and/or over an area where a common source line contact may be formed, and/or may be formed to be larger than a common source line contact. In embodiments, bridge 25 may be formed simultaneously with device isolation layer 5. In embodiments, during a photolithography process to form a trench of device isolation layer 5, bridge 25 may be formed by forming trenches having the same interval with bit lines while leaving an area where a common source line contact may be formed, to be connected to neighboring active area 10. In embodiments, bridge 25 may be formed in plural on and/or over common source line area 15. In embodiments, device isolation layer 5 may be disposed between a plurality of bridges 25.

According to embodiments, an active area of common source line area 15 where a common source line contact may be formed may also be formed including substantially the same interval with active area 10 of a bit line. In embodiments, bit lines may be substantially uniformly formed. In embodiments, characteristics of a memory device may be maximized. In embodiments, bridge 25 may connect two active areas 10, but embodiments are not limited thereto. In embodiments, bridge 25 may connect at least two neighboring active areas 10.

According to embodiments, a memory gate may be formed on and/or over semiconductor substrate 100, for example, after forming active area 10 including bridge 25. In embodiments, a memory gate may include a stack gate type. In embodiments, a floating gate may be formed including polysilicon. In embodiments, a memory gate is not limited thereto. In embodiments, a memory gate may include a silicon-oxide-nitride-oxide silicon (SONOS) type memory structure.

Referring to FIG. 2, control gate 20 may be formed on and/or over semiconductor substrate, over which a memory gate may be formed. According to embodiments, control gate 20 may include polysilicon. In embodiments, control gate 20 may be formed to be intersected with active area 10. In embodiments, a process including ion implantation, for example, may be performed on and/or over semiconductor substrate 100 to form a source and/or a drain.

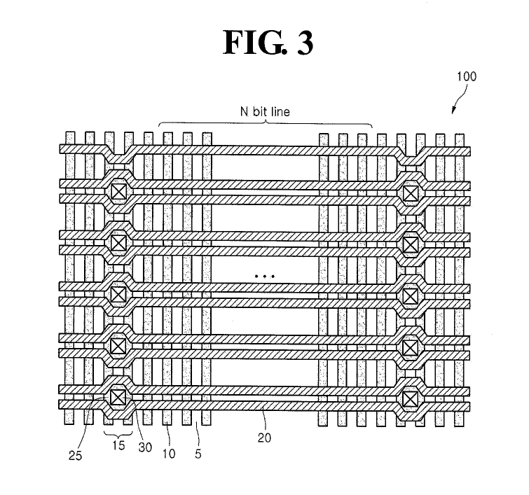

Referring to FIG. 3, common source line contact 30 may be formed on and/or over bridge 25, which may be formed on and/or over common source line area 15 of semiconductor substrate 100. According to embodiments, common source line contact 30 may form a common source line contact by forming an interlayer dielectric layer on and/or over semiconductor substrate 100, forming a via hole on and/or over a interlayer dielectric layer and/or burying a via hole with a metal material. In embodiments, common source line contact 30 may be formed to correspond to an area over which bridge 25 may be formed.

According to embodiments, bridge 25 may be formed on and/or over an area where common source line contact 30 may be formed. In embodiments, active areas of common source line area 15 may be formed having substantially the same interval with active areas 10 of bit lines. In embodiments, bit lines may be substantially uniformly formed. In embodiments, characteristics of a memory device may be maximized. In embodiments, common source line area 15 including bridge 25 may be formed to apply voltage in common a N bit line unit. In embodiments, common source contact 30 may be formed to apply voltage to a word line.

Embodiments relate to a flash memory device. Referring to FIG. 3, a plan view illustrates a flash memory device in accordance with embodiments. According to embodiments, a flash memory device may include device isolation layer 5 and/or active area 10 formed on and/or over semiconductor substrate 100. In embodiments, a flash memory device may include a memory gate formed on and/or over active area 10. In embodiments, a flash memory device may include control gate 20 formed on and/or over semiconductor substrate 100 including a memory gate. In embodiments, active areas 10 may be formed including substantially the same interval with bit lines. In embodiments, common source line area 15 where common source line contact 30 may be formed may include a bridge 25 formed between active areas 10, such that the neighboring active areas 10 may be connected.

According to embodiments, bridge 25 may connect at least two active areas 10. In embodiments, common source line contact 30 may be formed on and/or over an area where bridge 25 of active area 10 may be formed. In embodiments, a plurality of bridges 25 may be formed on and/or over common source line area 15 where common source line contact 30 may be formed. In embodiments, device isolation layers 5 may be disposed between a plurality of bridges 25. In embodiments, bridge 25 may be formed on and/or over an area where common source line contact 30 may be formed. In embodiments, active areas of common source line area 15 may be formed including substantially the same interval with active areas 10 of bit lines. In embodiments, bit lines may be substantially uniformly formed. In embodiments, characteristics of a memory device may be maximized.

According to embodiments, a method of manufacturing a flash memory device and a flash memory device may include active areas of a common source line area which may be formed having substantially the same interval with those of a bit line area. In embodiments, bridges connecting active areas may be formed on and/or over an area where a common source line contact may be formed. In embodiments, bit lines may be substantially uniformly formed. In embodiments, characteristics of a memory device may be maximized.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is :

1. An apparatus comprising:
a device isolation layer and active areas over a semiconductor substrate;
at least one of a memory gate and a control gate over said semiconductor substrate; and
a common source line area comprising a bridge between said active areas,
wherein said active areas comprises substantially the same interval as an interval of active areas of a bit line.

2. The apparatus of claim 1, wherein neighboring active areas are connected.

3. The apparatus of claim 1, wherein said bridge connects at least two active areas.

4. The apparatus of claim 1, comprising a common source line contact over an area where said bridge is formed.

5. The apparatus of claim 1, comprising a plurality of bridges over said common source line area where a common source line contact is formed.

6. The apparatus of claim 5, wherein said device isolation layer is disposed between said plurality of bridges.

7. The apparatus of claim 1, comprising a flash memory device.

8. The apparatus of claim 1, wherein said memory gate comprises at least one of:
a stack gate type; and
a silicon-oxide-nitride-oxide-silicon structure.

9. The apparatus of claim 8, comprising a floating gate including polysilicon.

10. A method comprising:
forming a device isolation layer and active areas over a semiconductor substrate;
forming at least one of a memory gate and a control gate over said semiconductor substrate; and
forming a common source line area comprising a bridge between said active areas,
wherein said active areas comprises substantially the same interval as an interval of active areas of a bit line.

11. The method of claim 10, wherein neighboring active areas are connected.

12. The method of claim 10, wherein said bridge connects at least two active areas.

13. The method of claim 10, comprising forming a common source line contact over an area where said bridge is formed.

14. The method of claim 10, comprising forming a plurality of bridges over said common source line area where a common source line contact is formed.

15. The method of claim 14, wherein said device isolation layer is disposed between said plurality of bridges.

16. The method of claim 10, comprising forming a flash memory device.

17. The method of claim 10, wherein said memory gate comprises a stack gate type.

18. The method of claim 17, comprising forming a floating gate including polysilicon.

19. The method of claim 10, wherein said memory gate comprises a silicon-oxide-nitride-oxide-silicon structure.

20. The method of claim 10, wherein said bridge is formed simultaneously with said device isolation layer.
